(19) United States
(12) Patent Application Publication
(10) Pub. No.: US 2007/0287295 A1
(43) Pub. Date: Dec. 13, 2007

(54) Adaptively Plasma Source And Method Of Processing Semiconductor Wafer Using The Same

(76) Inventor: Nam Hun Kim, Gyeoggi-do (KR)

Correspondence Address: MORGAN & FINNEGAN, L.L.P., 3 WORLD FINANCIAL CENTER, NEW YORK, NY, 10281-2101, US

(21) Appl. No.: 11/662,771

(22) PCT Filed: May 27, 2005
(86) PCT No.: PCT/KR05/01585

§ 371 Date: Mar. 13, 2007

(30) Foreign Application Priority Data
Sep. 14, 2004 (KR) 10-2004-0073519
May 20, 2005 (KR) 10/2005-0042644

(51) Int. Cl. C23F 1/08; H01L 21/3065

(52) U.S. Cl. 438/706; 156/345.35

(57) ABSTRACT

An adaptive plasma source, and a method for processing a semiconductor wafer using the same are disclosed. The adaptive plasma source comprises a first planar bushing equipped at an upper center of a reaction chamber defining a reaction space for processing a semiconductor wafer so as to face a planar electrode equipped at a lower portion of the reaction chamber, and a coil assembly spirally extending from the first bushing at an upper portion of the reaction chamber and surrounding the first bushing. The adaptive plasma source allows an etching process to be performed by freely controlling etching characteristics of a coupled plasma source and an inductively coupled plasma source according to a method for processing a semiconductor wafer which will be performed, thereby enabling the etching process having different conditions to be performed in a single apparatus.

### BACKGROUND OF THE INVENTION

1. Field of the Invention

The present invention relates to a semiconductor manufacturing apparatus and a method for processing a semiconductor wafer using the same. More particularly, the present invention relates to an adaptive plasma source and a method for processing a semiconductor wafer using the same.

2. Description of the Related Art

In general, an etching process, in particular, a dry etching process is a process for removing a predetermined portion of a lower layer according to a photoresist layer pattern or a hard mask pattern over a semiconductor wafer using plasma. It is necessary to generate plasma in a reaction chamber in order to perform such a dry etching process. Sources for generating the plasma can be classified into an inductively coupled plasma source (“ICP source”) and a capacitively coupled plasma source (“CCP source”).

FIG. 1 is a schematic view illustrating a conventional capacitively coupled plasma source.

As shown in FIG. 1, an etching chamber 100 employing the capacitively coupled plasma source comprises a lower electrode 110 located at a lower portion of the etching chamber 100, and an upper electrode 120 located at an upper portion of the etching chamber 110 so as to face the lower electrode 110. Both upper and lower electrodes 120 and 110 have a planar shape, and plasma is generated within the etching chamber 100 using characteristics of a capacitor formed by these two electrodes. When using such a CCP source, there is a disadvantage of low plasma density, leading to high power consumption, in spite of advantages such as high reproducibility of the process and high photoresist layer-etching selectivity.

FIG. 2 is a schematic view illustrating a conventional inductively coupled plasma source.

As shown in FIG. 2, an etching chamber 200 employing the inductively coupled plasma source comprises a lower electrode 210 located at a lower portion of the etching chamber 200, and a coil 220 located at an upper portion of the etching chamber 110 so as to face the lower electrode 210. The lower electrode 210 has a planar shape, and can generate plasma within the etching chamber 200 using characteristics of an inductor formed by the coil 220. When using such an ICP source, there are advantages of high etching rate and high plasma density, leading to lower power consumption. Additionally, the ICP source enables independent control of the plasma density and ion energy. On the other hand, with the ICP source, there are disadvantages of low photoresist layer-etching selectivity, low reproducibility of the process, and possibility of contamination on an aluminum dome, if one is used.

As described above, the CCP source and ICP source are contradictory to each other in terms of advantages and disadvantages. As a result, in any of the conventional plasma sources, either etching selectivity or satisfactory etching rate can be secured, but not both.

### SUMMARY OF THE INVENTION

Therefore, the present invention has been made in view of the above problems, and it is an object of the present invention to provide an adaptive plasma source, which can provide both characteristics of a CCP source and characteristics of an ICP source.

It is another object of the present invention to provide an adaptive plasma source, which allows an etching rate and a photoresist-etching selectivity to be adjusted, thereby permitting a higher etching rate and photoresist-etching selectivity.

It is yet another object of the present invention to provide a method for processing a semiconductor wafer using the adaptive plasma source.

In accordance with an aspect of the present invention, the above and other objects can be accomplished by the provision of an adaptive plasma source, comprising: a first planar bushing equipped at an upper center of a reaction chamber defining a reaction space for processing a semiconductor wafer so as to face a planar electrode equipped at a lower portion of the reaction chamber; and a coil assembly spirally extending from the first bushing at an upper portion of the reaction chamber and surrounding the first bushing.

The adaptive plasma source may further comprise at least one second bushing equipped at the upper portion of the reaction chamber so as to surround the first bushing.

The coil assembly may comprise a plurality of coils.

In accordance with another aspect of the present invention, an adaptive plasma source is provided, comprising: a first planar bushing vertically equipped in a column shape at an upper center of a reaction chamber defining a reaction space for processing a semiconductor wafer so as to face a planar electrode equipped at a lower portion of the reaction chamber, and having a first surface and a second surface formed on upper and lower ends of the column shape, respectively; a lower coil assembly spirally extending from the first surface of the first bushing and coplanar with the first surface while surrounding the first surface of the first bushing; and an upper coil assembly spirally extending from the second surface of the first bushing and coplanar with the second surface while surrounding the second surface of the first bushing.

The adaptive plasma source may further comprise at least one second bushing equipped to surround at least one of the first and second surfaces.

At least one of the upper and lower coil assemblies may comprise a plurality of coils.

In accordance with yet another aspect of the present invention, a method for etching a semiconductor wafer is provided, using an adaptive plasma source comprising: a first planar bushing equipped at an upper center of a reaction chamber defining a reaction space for processing a semiconductor wafer so as to face a planar electrode equipped at a lower portion of the reaction chamber; and at least one coil spirally extending from the first bushing and surrounding the first bushing at an upper portion of the reaction chamber, wherein characteristics of the adaptive plasma source are determined by χ=ICP/(ICP+CCP), where χ is a characteristic value of the adaptive plasma source, ICP is a characteristic value of inductively coupled plasma determined by the planar electrode and the coil, and CCP is a characteristic value of capacitively coupled plasma determined by the planar electrode and the first bushing.

When increasing an etching rate relative to an etching selectivity, the adaptive plasma source may be set to have the characteristic value χ of the adaptive plasma source close to 1.

When increasing the etching selectivity relative to the etching rate, the adaptive plasma source may be set to have the characteristic value χ of the adaptive plasma source close to 0.

The adaptive plasma source may be set by controlling the number of coils, spacing between the coils, thickness of the coils, size of the bushings, and a material of the bushings.

In accordance with yet another aspect of the present invention, an adaptive plasma source is provided, comprising: a planar bushing equipped at an upper center of a reaction chamber defining a reaction space for processing a semiconductor wafer; a support rod equipped to protrude from the center of the bushing in an opposite direction to the reaction chamber; and a coil assembly spirally extending from the support rod and surrounding the support rod above the bushing.

A portion of the coil assembly may overlap the bushing.

The coil assembly may comprise a plurality of coils.

The bushing may have a circular shape, the center of which is defined by a point connected to the support rod.

The adaptive plasma source may further comprise an assistant bushing equipped above the coil assembly such that a center of the assistant bushing is penetrated by the support rod.

The assistant bushing may have a circular shape, the center of which is defined by a point connected to the support rod.

The assistant bushing may have a cross-sectional area smaller than that of the bushing.

In accordance with still another aspect of the present invention, an adaptive plasma source is provided, comprising: a planar bushing equipped at an upper center of a reaction chamber defining a reaction space for processing a semiconductor wafer; a support rod equipped to penetrate the center of the bushing and protrude through upper and lower ends of the bushing; and a coil assembly spirally extending from the support rod protruded from the lower end of the busing, and surrounding the support rod below the bushing.

A portion of the bushing may overlap the coil.

The coil assembly may comprise a plurality of coils.

The bushing may have a circular shape, the center of which is defined by a point connected to the support rod.

The adaptive plasma source may further comprise an assistant coil spirally extending from the support rod protruded from the upper end of the bushing, and surrounding the support rod above the bushing.

As apparent from the above description, the adaptive plasma source according to the one aspect of the present invention provides all advantages of a capacitively coupled plasma source and an inductively coupled plasma source, and, in particular, allows an etching process to be performed by freely adjusting etching characteristics of the capacitively coupled plasma source and the inductively coupled plasma source according to a method for processing a semiconductor wafer, thereby enabling an etching process having different conditions to be performed in a single apparatus.

Additionally, the adaptive plasma source according to the other aspect of the present invention is provided with an assistant bushing or an assistant coil so as to have various structures, thereby enabling one or both of an etching rate and a photoresist-etching selectivity to be selectively increased.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a schematic view illustrating a conventional capacitively coupled plasma source;

FIG. 2 is a schematic view illustrating a conventional inductively coupled plasma source;

FIG. 3 is a schematic view illustrating the structure of an adaptive plasma source in accordance with the present invention;

FIG. 4 is a plan view illustrating one embodiment of the adaptive plasma source of FIG. 3;

FIG. 5 is a cross-sectional view taken along line A-A′ of the adaptive plasma source of FIG. 4;

FIG. 6 is a plan view illustrating another embodiment of the adaptive plasma source of FIG. 3;

FIG. 7 is a cross-sectional view taken along line B-B′ of the adaptive plasma source of FIG. 6;

FIG. 8 is a plan view illustrating yet another embodiment of the adaptive plasma source of FIG. 3;

FIG. 9 is a cross-sectional view taken along line C-C′ of the adaptive plasma source of FIG. 8;

FIG. 10 is a plan view illustrating yet another embodiment of the adaptive plasma source of FIG. 3;

FIG. 11 is a graphical representation illustrating a method for processing a semiconductor wafer using the adaptive plasma source in accordance with the present invention;

FIG. 12 is a plan view illustrating yet another embodiment of the adaptive plasma source of FIG. 3;

FIG. 13 is a cross-sectional view taken along line D-D′ of the adaptive plasma source of FIG. 12;

FIG. 14 is a graphical representation depicting characteristics of an etching rate and an etching selectivity of the adaptive plasma source of FIG. 12;

FIG. 15 is a plan view illustrating yet another embodiment of the adaptive plasma source of FIG. 3;

FIG. 16 is a cross-sectional view taken along line E-E′ of the adaptive plasma source of FIG. 15;

FIG. 17 is a graphical representation depicting characteristics of an etching rate and an etching selectivity of the adaptive plasma source of FIG. 15;

FIG. 18 is a plan view illustrating yet another embodiment of the adaptive plasma source of FIG. 3;

FIG. 19 is a cross-sectional view taken along line F-F′ of the adaptive plasma source of FIG. 15;

FIG. 20 is a graphical representation depicting characteristics of an etching rate and an etching selectivity of the adaptive plasma source of FIG. 18;

FIG. 21 is a plan view illustrating still another embodiment of the adaptive plasma source of FIG. 3;

FIG. 22 is a cross-sectional view taken along line G-G′ of the adaptive plasma source of FIG. 21; and

FIG. 23 is a graphical representation depicting characteristics of an etching rate and an etching selectivity of the adaptive plasma source of FIG. 21.

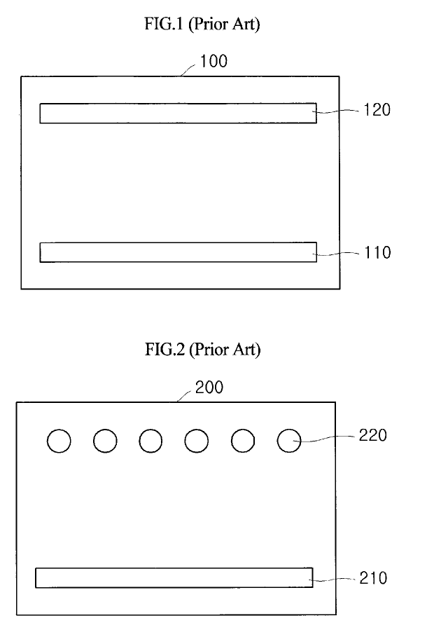

### DESCRIPTION OF THE PREFERRED EMBODIMENTS

Preferred embodiment of the present invention will be described with reference to accompanying drawings.

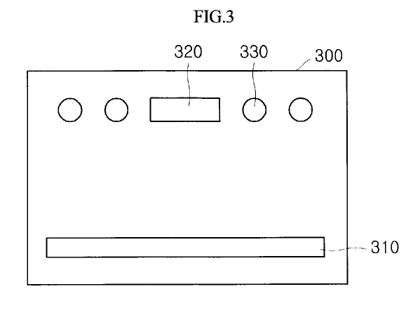

FIG. 3 is a schematic view illustrating an adaptive plasma source in accordance with the present invention.

As shown in FIG. 3, an etching chamber 300 employing the adaptive plasma source of the invention comprises a lower planar electrode 310 equipped at a lower portion of the etching chamber 300, and adaptive plasma sources 320 and 330 equipped at an upper center of the etching chamber 300 so as to face the lower planar electrode 110. The adaptive plasma source 320 and 330 comprises a planar bushing 320, and a coil 330 spirally extending from the bushing 320 at the upper portion of the etching chamber 300 and surrounding the bushing 320.

The adaptive plasma source can be generally classified into two types. One is a single stack adaptive plasma source, and the other is a multi-stack adaptive plasma source. Herein, the term “single stack” means a structure of a single layer, and the term “multi-stack” means a structure of multiple layers. More specifically, the single stack adaptive plasma source only comprises the bushing 320 and the coil 330 located on a first plane of the upper portion of the etching chamber 300, whereas the multi-stack adaptive plasma source comprises one or more bushings and coils located on a second surface vertically higher than the first plane in addition to the bushing 320 and the coil 330 located on the first plane of the upper portion of the etching chamber 300.

Each of the single stack adaptive plasma source and the multi-stack adaptive plasma source can be classified into a single coil structure comprising a single coil, and a multi-coil structure comprising a plurality of coils. Both single coil structure and multi-coil structure may have a single bushing structure comprising a single bushing, or a multi-bushing structure comprising a plurality of bushings.

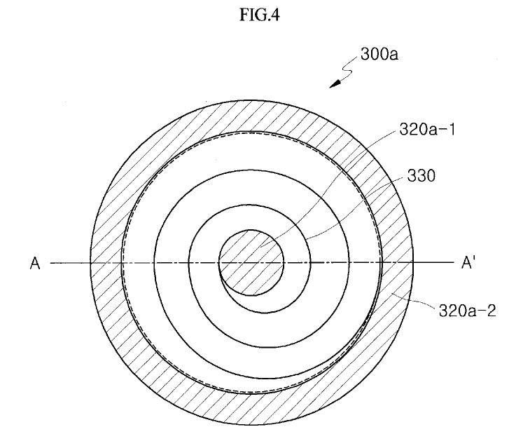

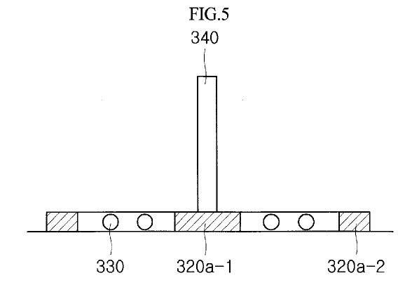

FIG. 4 is a plan view illustrating one embodiment of the adaptive plasma source of FIG. 3, and FIG. 5 is a cross-sectional view taken along line A-A′ of the adaptive plasma source of FIG. 4.

Referring to FIGS. 4 and 5, an adaptive plasma source 300a according to the present embodiment comprises a first bushing 320a-1 located at the center of the plasma source 300a, a second bushing 320a-2 separated a predetermined distance from the first bushing 320a-1 while surrounding the first bushing 320a-1, and a coil 330 spirally extending from the first bushing 320a-1 to the second bushing 320a-2 and surrounds the first bushing 320a-1. Accordingly, the adaptive plasma source 300a according to the present embodiment has the single stack structure comprising a single coil and multiple bushings. A column 340 is disposed on the first bushing 320a-1 to electrically connect the first bushing 320a-1 to an external RF source (not shown).

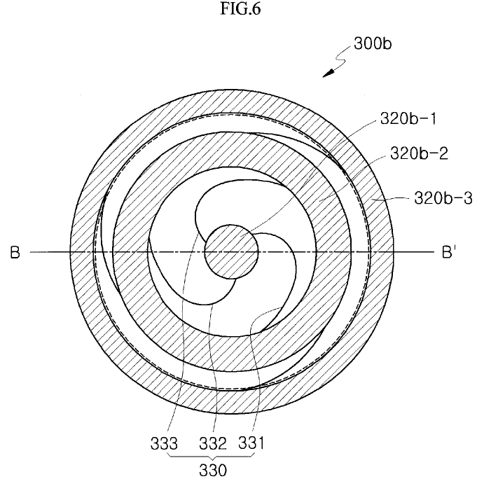

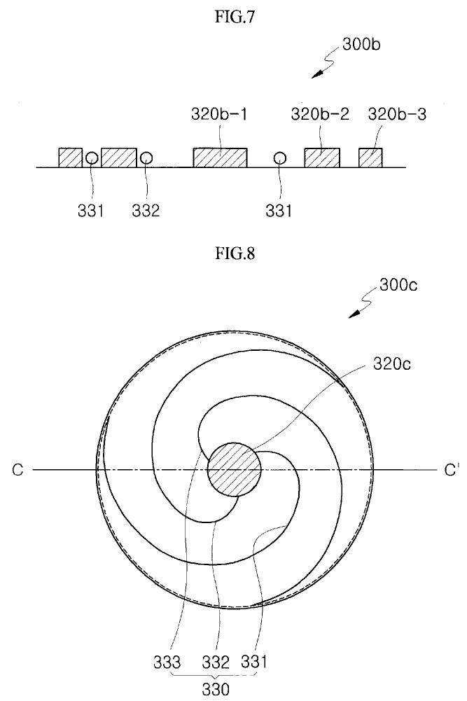

FIG. 6 is a plan view illustrating another embodiment of the adaptive plasma source of FIG. 3, and FIG. 7 is a cross-sectional view taken along line B-B′ of the adaptive plasma source of FIG. 6.

Referring to FIGS. 6 and 7, an adaptive plasma source 300b according to the present embodiment comprises a first bushing 320b-1 located at the center of the plasma source 300b, a second bushing 320b-2 separated a predetermined distance from the first bushing 320b-1 while surrounding the first bushing 320b-1, and a third bushing 320b-3 separated at a predetermined distance from the second bushing 320b-2 while surrounding the second bushing 320b-2. The adaptive plasma source 300b further comprises a coil assembly 330 which spirally extends from the first bushing 320b-1 to the second bushing 320b-2 and surrounds the first bushing 320b-1, and which spirally extends from the second bushing 320b-2 to the third bushing 320b-3 and surrounds the second bushing 320b-2. At this time, the coil assembly 330 comprises a first coil 331, a second coil 332, and a third coil 331 uniformly separated from each other. Accordingly, the adaptive plasma source 300b according to the present embodiment has the single stack structure comprising multiple coils and multiple bushings.

FIG. 8 is a plan view illustrating yet another embodiment of the adaptive plasma source of FIG. 3, and FIG. 9 is a cross-sectional view taken along line C-C′ of the adaptive plasma source of FIG. 8.

Referring to FIGS. 8 and 9, an adaptive plasma source 300c according to the present embodiment comprises a bushing 320c located at the center of the plasma source 300c, and a coil assembly 330 which spirally extends from the bushing 320c and surrounds the bushing 320c. At this time, the coil assembly 330 comprises a first coil 331, a second coil 332, and a third coil 331 uniformly separated from each other. Accordingly, the adaptive plasma source 300c according to the present embodiment has the single stack structure comprising multiple coils and a single bushing. Meanwhile, the adaptive plasma source 300c according to the present embodiment is disposed on a convex dome 600, which is thickest at the center thereof and is gradually decreases in thickness towards both ends. With this structure, a distance between the bushing 320c and an inner space of a chamber below the dome 600 is different from a distance between the coil assembly 330 and the inner space of the chamber below the dome 600, thereby reducing deviation in plasma density within the chamber.

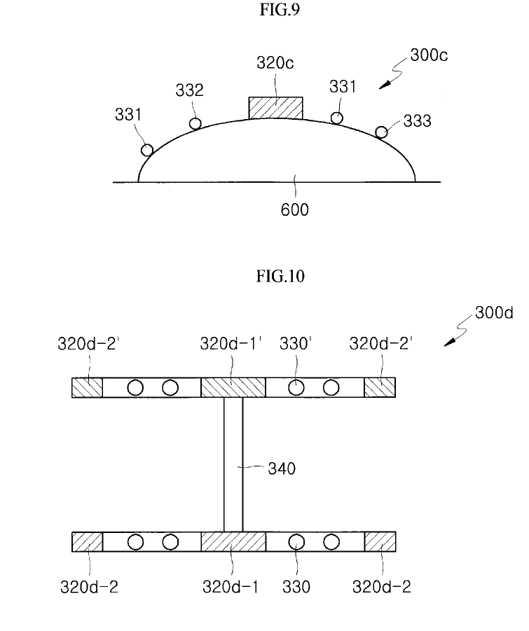

FIG. 10 is a cross-sectional view illustrating yet another embodiment of the adaptive plasma source of FIG. 3.

Referring to FIG. 10, an adaptive plasma source 300d according to the present embodiment comprises first lower and upper bushings 320d-1 and 320d-1′ equipped at both ends of a vertical column 340 located at the center of the plasma source 300d. A second lower bushing 320d-2 is separated at a predetermined distance from the first lower bushing 320d-1 while surrounding the first lower bushing 320d-1. As with the second lower bushing 320d-2, a second upper bushing 320d-2′ is separated at a predetermined distance from the first upper bushing 320d-1′ while surrounding the first upper bushing 320d-1′. The adaptive plasma source 300d according to the present embodiment further comprises a lower coil assembly 330, which spirally extends from the first lower bushing 320d-1 to the second lower bushing 320d-2 and surrounds the first lower bushing 320d-1, and an upper coil assembly 330′, which spirally extends from the first upper bushing 320d-1′ to the second upper bushing 320d-2′ and surrounds the first upper bushing 320d-1′. In the adaptive plasma source 300d according to the present embodiment, the structure disposed at the lower portion of the plasma source, and the structure disposed at the upper portion thereof have the same planar structure as shown in FIG. 4. In some cases, the adaptive plasma source 300d may comprise an integral structure of the first lower and upper bushings 320d-1 and 320d-1′. More specifically, the bushings can be formed in a cylindrical shape having a predetermined diameter, wherein the bottom of the cylindrical shape constitutes a lower surface of the first lower bushing 320d-1, and the top of the cylindrical shape constitutes an upper surface of the first upper bushing 320d-1′. The adaptive plasma source 300d according to the present embodiment has a multi-stack structure having a single coil and multiple bushings.

FIG. 11 is a graphical representation illustrating a method for processing a semiconductor wafer using the adaptive plasma source in accordance with the present invention.

Referring to FIG. 11, the adaptive plasma source according to the invention concurrently exhibits characteristics of an ICP source and a CCP source, which can be illustrated using the following equation.
χ=ICP/(OCP+CCP)

where χ is a characteristic value of the adaptive plasma source, ICP is a characteristic value of inductively coupled plasma determined by the planar electrode and the coil, and CCP is a characteristic value of capacitively coupled plasma determined by the planar electrode and the first bushing.

As described above, the characteristics of the capacitively coupled plasma include a high photoresist-etching selectivity 810 and a low etching rate 820, whereas the characteristics of the inductively coupled plasma include a low photoresist-etching selectivity 810 and a high etching rate 820. In the above equation, if the adaptive plasma source has a characteristic value 830 of χ=0, the characteristics of the adaptive plasma source are the same as the characteristics of the capacitively coupled plasma, that is, CCP, and if the adaptive plasma source has a characteristic value 830 of χ=1, the characteristics of the adaptive plasma source are the same as the characteristics of the inductively coupled plasma, that is, ICP. As shown in FIG. 11, the adaptive plasma source may have a characteristic value 830 of χ from 0 to 1. Variables determining the characteristic value of the adaptive plasma source include the number of coils, spacing between the coils, thickness of the coils, size of the bushings, the number of bushings, the material of the bushing, and the like. Accordingly, when increasing the etching rate relative to the etching selectivity by controlling these variables, the adaptive plasma source may be set to have the characteristic value χ of the adaptive plasma source close to 1. On the contrary, When increasing the etching selectivity relative to the etching rate, the adaptive plasma source may be set to have the characteristic value χ of the adaptive plasma source close to 0.

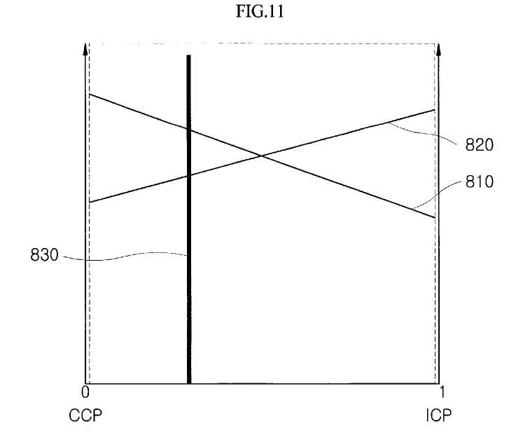

FIG. 12 is a plan view illustrating yet another embodiment of the adaptive plasma source of FIG. 3, and FIG. 13 is a cross-sectional view taken along line D-D′ of the adaptive plasma source of FIG. 12.

Referring to FIGS. 12 and 13, an adaptive plasma source 400 according to the present embodiment comprises a planar bushing 420 equipped at an upper center of a reaction chamber. Although the adaptive plasma source 400 of the present embodiment is illustrated in FIG. 12 as having a circular shape, it may have other shapes. A support rod 440 is equipped to the center of the bushing 420 such that it protrudes from an upper surface of the bushing 420 opposite to the lower surface of the bushing facing the reaction chamber. Although not shown in the drawing, an RF power source (not shown) is connected to the distal end of the support rod 440. The bushing 420 may be made of the same material as the support rod 440 or may be made of a different material. In either case, the support rod 440 is made of a conductive material.

The adaptive plasma source 400 further comprises a coil assembly 430 including first second, third and fourth coils 431, 432, 433 and 434. Although the present embodiment is described as having four coils, the present invention is not limited to this structure. Alternatively, the adaptive plasma source 400 may comprise any number of coils. The first, second, third and fourth coils 431, 432, 433 and 434 spirally extend from a side surface of the support rod 440 and surround the support rod 440. Accordingly, the first, second, third, and fourth coils 431, 432, 433, and 434 are located above the bushing 420, and a portion of each coil 431, 432, 433 or 434 overlaps the bushing 420. Power is transmitted from the RF power source connected to the distal end of the support rod 440 to the first, second, third, and fourth coils 431, 432, 433 and 434 through the support rod 440.

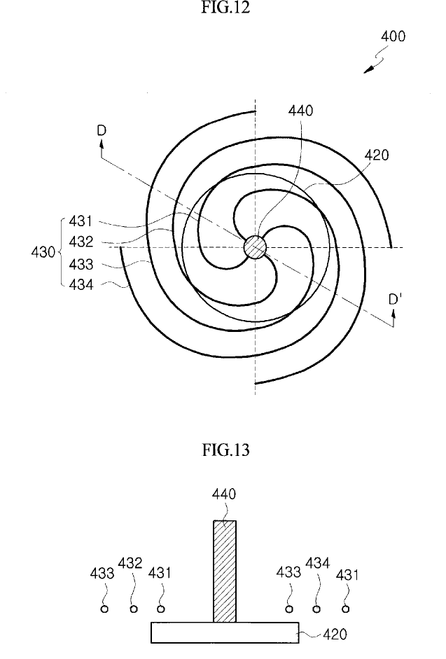

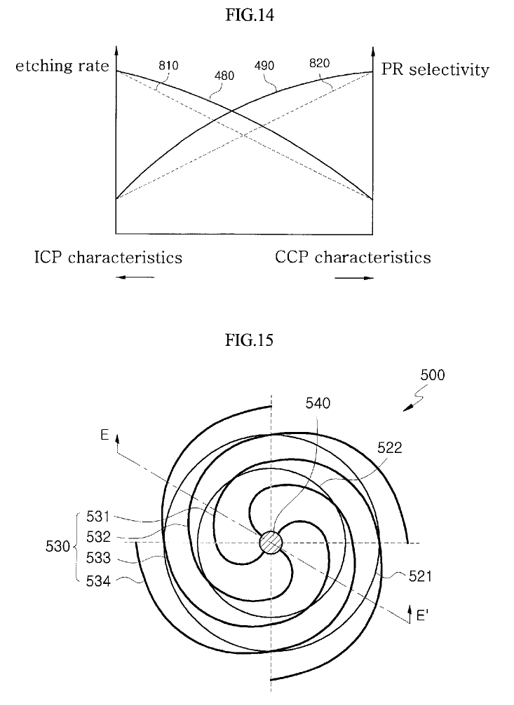

FIG. 14 is a graphical representation depicting characteristics of an etching rate and an etching selectivity of the adaptive plasma source of FIG. 12.

Referring to FIG. 14, in terms of the etching rate, the adaptive plasma source 400 according to the present embodiment is higher (as indicated by line 480 of FIG. 14) than the adaptive plasma sources according to the embodiments illustrated with reference to FIGS. 4 to 10 (as indicated by dotted line 810 of FIGS. 4 to 10). Additionally, in terms of the photoresist-etching selectivity, the adaptive plasma source 400 according to the present embodiment is higher (as indicated by line 490 of FIG. 14) than the adaptive plasma sources according to the embodiments illustrated with reference to FIGS. 4 to 10 (as indicated by dotted line 820 of FIGS. 4 to 10). With regard to this, an increasing ratio of the photoresist-etching selectivity is higher than that of the etching rate, which means that the characteristics of the capacitively coupled plasma source are further strengthened in comparison to the inductively coupled plasma source. The reason for strengthening in the characteristics of the capacitively coupled plasma source is that the adaptive plasma source 400 of the present embodiment comprises the bushing 440 having a larger cross-section than the adaptive plasma sources of the embodiments illustrated with reference to FIGS. 4 to 10. A strengthening degree of the capacity coupled plasma source can be controlled to a desired value by controlling the cross-section of the bushing 440. Similarly, the characteristics of the inductively coupled plasma source can also be controlled by changing designs of the first, second, third, and fourth coils 431, 432, 433 and 434.

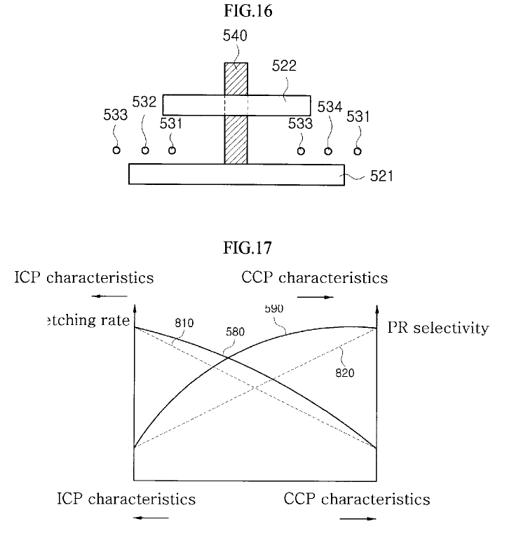

FIG. 15 is a plan view illustrating yet another embodiment of the adaptive plasma source of FIG. 3, and FIG. 16 is a cross-sectional view taken along line E-E′ of the adaptive plasma source of FIG. 15.

Referring to FIGS. 15 and 16, an adaptive plasma source 500 according to the present embodiment is different from the adaptive plasma source 400 described with reference to FIGS. 12 and 13 in that the adaptive plasma source 500 further comprises an assistant bushing 522 equipped above a coil assembly 530 including, for example, first, second, third, and fourth coils 531, 532, 533 and 534. More specifically, the adaptive plasma source 500 of the present embodiment comprises a main planar bushing 521 equipped at an upper center of the reaction chamber, and an assistant bushing 522 positioned a predetermined distance above the main bushing 521 in the vertical direction. In the present embodiment, the assistant bushing 522 has a cross-section smaller than that of the main bushing 521. However, without being limited to this structure, the assistant bushing 522 may have an equal or larger cross-section than the main bushing 521.

A support rod 540 is equipped through the center of the main bushing 521 and the assistant bushing 522. That is, the support rod 540 extends from the center of the main bushing 521 towards the assistant bushing 522, and penetrates the assistant bushing 522 above an upper surface of the assistant bushing 522. Although not shown in the figure illustrating the present embodiment, an RF power source (not shown) is connected to a distal end of the support rod 540. The main bushing 521, the assistant bushing 522, and the support rod 540 may be made of the same material or different materials. In either case, the support rod 540 is made of a conductive material.

The adaptive plasma source 500 further comprises the coil assembly 530 including the first, second, third, and fourth coils 531, 532, 533, and 534 between the main bushing 521 and the assistant bushing 522. The first, second, third, and fourth coils 531, 532, 533 and 534 are equipped to the adaptive plasma source 500 in such a manner of spirally extending from a side surface of the support rod 540 between the main bushing 521 and the assistant bushing 522 and then surrounding the support rod 540. Accordingly, portions of the first, second, third, and fourth coils 531, 532, 533 and 534 overlap the main bushing 521 and the assistant bushing 522, respectively. Power is transmitted from the RF power source connected to the distal end of the support rod 540 to the first, second, third, and fourth coils 531, 532, 533 and 534 through the support rod 540.

FIG. 17 is a graphical representation depicting characteristics of an etching rate and an etching selectivity of the adaptive plasma source of FIG. 15.

Referring to FIG. 17, in terms of the etching rate, the adaptive plasma source 500 according to the present embodiment is higher (as indicated by line 580 of FIG. 17) than the adaptive plasma sources according to the embodiments illustrated with reference to FIGS. 4 to 10 (as indicated by dotted line 810 of FIGS. 4 to 10). Additionally, in terms of the photoresist-etching selectivity, the adaptive plasma source 500 according to the present embodiment is higher (as indicated by line 590 of FIG. 14) than the adaptive plasma sources according to the embodiment illustrated with reference to FIGS. 4 to 10 (as indicated by dotted line 820 of FIGS. 4 to 10). As with the above embodiments, the increasing ratio of the photoresist-etching selectivity is higher than that of the etching rate, which means that the characteristics of the capacitively coupled plasma source are further strengthened in comparison to the inductively coupled plasma source. In particular, the strengthening degree for the coupled plasma source can be controlled to a desired value by controlling the cross-sections of the main bushing 521 and the assistant bushing 522. Similarly, the characteristics of the inductively coupled plasma source can also be controlled by changing designs of the first, second, third, and fourth coils 531, 532, 533 and 534.

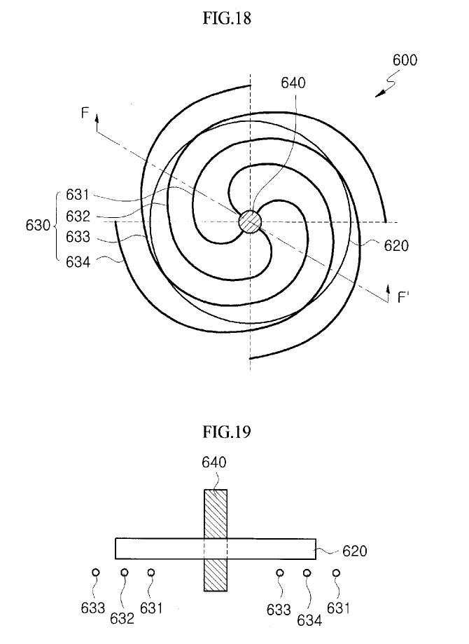

FIG. 18 is a plan view illustrating yet another embodiment of the adaptive plasma source of FIG. 3, and FIG. 19 is a cross-sectional view taken along line F-F′ of the adaptive plasma source of FIG. 18.

Referring to FIGS. 18 and 19, an adaptive plasma source 600 according to the present embodiment comprises a planar bushing 620 equipped at an upper center of the reaction chamber. A support rod 640 is equipped at the center of the bushing 620 such that it protrudes from an upper surface of the bushing 620 opposite to a lower surface of the bushing 620 facing the reaction chamber. Although not shown in the drawing, an RF power source (not shown) is connected to a distal end of the support rod 640.

The adaptive plasma source 600 further comprises a coil assembly 630 including first, second, third, and fourth coils 631, 632, 633 and 634 below the bushing 620, which spirally extend from the side surface of the support rod 640 and surround the support rod 640. Accordingly, the first, second, third, and fourth coils 631, 632, 633 and 634 are located between the lower surface of the bushing 620 and the reaction chamber. That is, the adaptive plasma source 600 of the present embodiment is different from the adaptive plasma source 400 having the coils located above the bushing 420 as shown in FIG. 12 in that the first, second, third, and fourth coils 631, 632, 633 and 634 are located below the bushing 620.

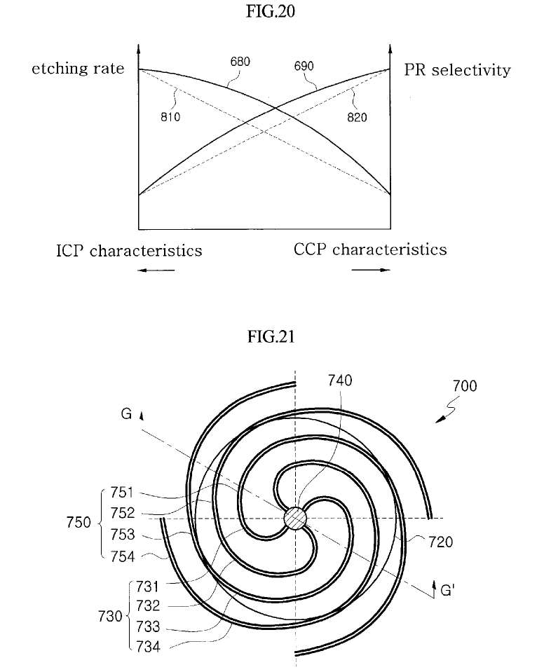

FIG. 20 is a graphical representation depicting characteristics of an etching rate and etching selectivity of the adaptive plasma source of FIG. 18.

Referring to FIG. 20, in terms of the etching rate, the adaptive plasma source 600 according to the present embodiment is higher (as indicated by line 680 of FIG. 20) than the adaptive plasma sources according to the embodiments illustrated with reference to FIGS. 4 to 10 (as indicated by the dotted line 810 of FIGS. 4 to 10). This is because the coil assembly 630 is located closer to the reaction chamber (not shown). Additionally, in terms of the photoresist-etching selectivity, the adaptive plasma source 600 according to the present embodiment is higher (as indicated by line 690 of FIG. 20) than the adaptive plasma sources according to the embodiments illustrated with reference to FIGS. 4 to 10 (as indicated by the dotted line 820 of FIGS. 4 to 10). This is because the bushing 620 of the adaptive plasma source 600 has a larger cross-section than those of the adaptive plasma sources of the other embodiments described with reference to FIGS. 4 to 10. Meanwhile, an increasing ratio of the etching rate is higher than that of the photoresist-etching selectivity, which means that the characteristics of the inductively coupled plasma source are further strengthened in comparison to the capacitively coupled plasma source. In particular, a strengthening degree for the inductively coupled plasma source can be controlled to a desired value by controlling the design of the coil assembly 630, and the distance between the reaction chamber and the coil assembly 630. Similarly, the characteristics of the capacitively coupled plasma source can also be controlled by changing the cross-section of the bushing 620.

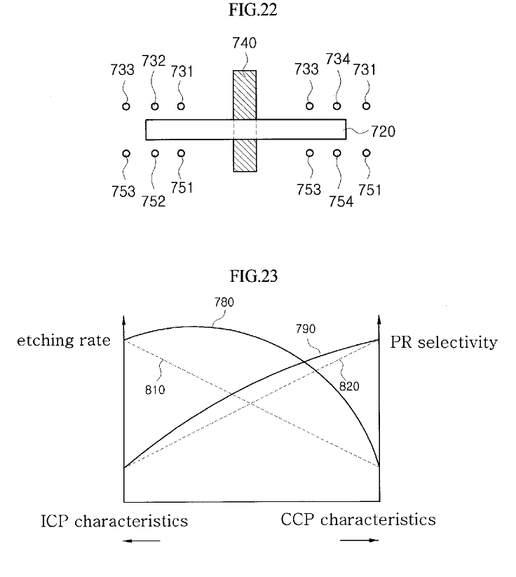

FIG. 21 is a plan view illustrating still another embodiment of the adaptive plasma source of FIG. 3, and FIG. 22 is a cross-sectional view taken along line G-G′ of the adaptive plasma source of FIG. 21.

Referring to FIGS. 21 and 22, an adaptive plasma source 700 according to the present embodiment is different from the adaptive plasma source 600 described with reference to FIGS. 18 and 19 in that the adaptive plasma source 700 further comprises a assistant coil assembly 730 including, for example, the first, second, third and fourth assistant coils 731, 732, 733 and 734, above a bushing 720. More specifically, the adaptive plasma source 700 of the present embodiment comprises the planar bushing 720 equipped at an upper center of the reaction chamber, a support rod 740 equipped at the center of the bushing 720, a main coil assembly 750, and the assistant coil assembly 750 equipped to the lower and upper portions of the bushing 720.

The main coil assembly 750 including, for example, first, second, third and fourth coils 751, 752, 753 and 754 is equipped below the bushing 720 such that the main coil assembly 750 spirally extends from a side surface of the support rod 740 and surrounds the support rod 740. As with the main coil assembly, the assistant coil assembly 730 including the first, second, third and fourth assistant coils 731, 732, 733 and 734 is equipped above the bushing 720 such that the assistant coils 730 extend from the side surface of the support rod 740 and spirally surround the support rod 740. As a result, portions of the first, second, third and fourth coils 751, 752, 753 and 754, and portions of the first, second, third and fourth assistant coils 731, 732, 733 and 734 overlap the bushing 720, respectively.

FIG. 23 is a graphical representation depicting characteristics of an etching rate and an etching selectivity of the adaptive plasma source of FIG. 21.

Referring to FIG. 23, in terms of the etching rate, the adaptive plasma source 700 according to the present embodiment is higher (as indicated by line 780 of FIG. 17) than the adaptive plasma sources according to the embodiments illustrated with reference to FIGS. 4 to 10 (as indicated by the dotted line 810 of FIGS. 4 to 10). Additionally, in terms of the photoresist-etching selectivity, the adaptive plasma source 700 according to the present embodiment is higher (as indicated by line 790 of FIG. 14) than the adaptive plasma sources according to the embodiments illustrated with reference to FIGS. 4 to 10 (as indicated by the dotted line 820 of FIGS. 4 to 10). Meanwhile, an increasing ratio of the etching rate is higher than that of the photoresist-etching selectivity, which means that the characteristics of the inductively coupled plasma source are further strengthened in comparison to the capacitively coupled plasma source. This is because the assistant coil assembly 730 is added. A strengthening degree for the inductively coupled plasma source can be controlled to a desired value by changing designs of the main and assistant coil assemblies 750 and 730. Similarly, the characteristics of the capacitively coupled plasma source can be controlled by altering the cross-sections of the bushing 720.

The present invention can be applied to an apparatus and a method for manufacturing a semiconductor employing a plasma chamber.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. An adaptive plasma source, comprising:
a first planar bushing equipped at an upper center of a reaction chamber defining a reaction space for processing a semiconductor wafer so as to face a planar electrode equipped at a lower portion of the reaction chamber; and
a coil assembly spirally extending from the first bushing at an upper portion of the reaction chamber and surrounding the first bushing.

2. The adaptive plasma source according to claim 1, further comprising:
at least one second bushing equipped at the upper portion of the reaction chamber so as to surround the first bushing.

3. The adaptive plasma source according to claim 1, wherein the coil assembly comprises a plurality of coils.

4. An adaptive plasma source, comprising:
a first planar bushing vertically equipped in a column shape at an upper center of a reaction chamber defining a reaction space for processing a semiconductor wafer so as to face a planar electrode equipped at a lower portion of the reaction chamber, and having a first surface and a second surface formed on upper and lower ends of the column shape, respectively;
a lower coil assembly spirally extending from the first surface of the first bushing and coplanar with the first surface while surrounding the first surface of the first bushing; and
an upper coil assembly spirally extending from the second surface of the first bushing and coplanar with the second surface while surrounding the second surface of the first bushing.

5. The adaptive plasma source according to claim 4, further comprising:
at least one second bushing equipped to surround at least one of the first and second surfaces of the first bushing.

6. The adaptive plasma source according to claim 4, wherein at least one of the upper and lower coil assemblies comprises a plurality of coils.

7. A method for etching a semiconductor wafer using an adaptive plasma source comprising: a first planar bushing equipped at an upper center of a reaction chamber defining a reaction space for processing a semiconductor wafer so as to face a planar electrode equipped at a lower portion of the reaction chamber; and at least one coil spirally extending from the first bushing and surrounding the first bushing at an upper portion of the reaction chamber, wherein characteristics of the adaptive plasma source are determined by χ=ICP/(ICP+CCP), where χ is a characteristic value of the adaptive plasma source, ICP is a characteristic value of inductively coupled plasma determined by the planar electrode and the coil, and CCP is a characteristic value of capacitively coupled plasma determined by the planar electrode and the first bushing.

8. The method according to claim 7, wherein, when increasing the etching rate relative to the etching selectivity, the adaptive plasma source is set to have the characteristic value χ of the adaptive plasma source close to 1.

9. The method according to claim 7, wherein, when increasing the etching selectivity relative to the etching rate, the adaptive plasma source is set to have the characteristic value χ of the adaptive plasma source close to 0.

10. The method according to claim 8 or 9, wherein the adaptive plasma source is set by controlling the number of coils, spacing between the coils, thickness of the coils, size of the bushings, the number of bushings, a material of the bushing.

11. An adaptive plasma source, comprising:
a planar bushing equipped at an upper center of a reaction chamber defining a reaction space for processing a semiconductor wafer;
a support rod equipped to protrude from a center of the bushing in an opposite direction of the reaction chamber, and
a coil assembly spirally extending from the support rod and surrounding the support rod above the bushing.

12. The adaptive plasma source according to claim 11, wherein a portion of the coil assembly overlaps the bushing.

13. The adaptive plasma source according to claim 11, wherein the coil assembly comprises a plurality of coils.

14. The adaptive plasma source according to claim 11, wherein the bushing has a circular shape, the center of which is defined by a point connected to the support rod.

15. The adaptive plasma source according to claim 11, further comprising:
an assistant bushing equipped above the coil assembly such that a center of the assistant bushing is penetrated by the support rod.

16. The adaptive plasma source according to claim 15, wherein the assistant bushing has a circular shape, the center of which is defined by a point connected to the support rod.

17. The adaptive plasma source according to claim 15, wherein the assistant bushing has a cross-section smaller than that of the bushing.

18. An adaptive plasma source, comprising:
a planar bushing equipped at an upper center of a reaction chamber defining a reaction space for processing a semiconductor wafer,
a support rod equipped to penetrate a center of the bushing and protrude from upper and lower ends of the bushing; and
a coil assembly spirally extending from the support rod protruded from the lower end of the busing, and surrounding the support rod below the bushing.

19. The adaptive plasma source according to claim 18, wherein a portion of the bushing overlaps the coil assembly.

20. The adaptive plasma source according to claim 18, wherein the coil assembly comprises a plurality of coils.

21. The adaptive plasma source according to claim 18, wherein the bushing has a circular shape, the center of which is defined by a point connected to the support rod.

22. The adaptive plasma source according to claim 18, further comprising:
an assistant coil spirally extending from the support rod protruded from the upper end of the bushing, and surrounding the support rod above the busing.
